(19) United States
(12) Patent Application Publication
(10) Pub. No.: US 2020/0388739 A1
(43) Pub. Date: Dec. 10, 2020

(54) THERMOELECTRIC POWER GENERATION

(71) Applicant: SANDEEP KUMAR CHINTALA, GREENFORD (GB)

(72) Inventors: SANDEEP KUMAR CHINTALA, SUTTON SURREY (GB); SRIRANJAN RASAKATLA, SHAMSHABAD HYDERABAD (IN)

(21) Appl. No.: 16/772,548

(22) PCT Filed: Dec. 13, 2018
(86) PCT No.: PCT/GB2018/053618

§ 371 Date: Jun. 12, 2020

(30) Foreign Application Priority Data
Dec. 13, 2017 (IN) 201741044867

(51) Int. Cl. H01L 35/02; H01L 35/30

(52) U.S. Cl. CPC H01L 35/02; H01L 35/30

(57) ABSTRACT

Techniques of thermoelectric power generation are described. In an example, a power generation system (100) may include a thermoelectric unit (102), a DC booster (104) and a supercapacitor unit (106). The thermoelectric unit (102) may generate electivity using heat, such as heat obtained from human body. The DC booster (104) may step up the voltage generated by the thermoelectric unit (102). The supercapacitor unit (106) may store electrical energy generated by the thermoelectric unit (102) and start discharging after a threshold level. The power generation system may be implemented to power a wearable device (304), such as fitness tracker and smartwatch.

### TECHNICAL FIELD

The present subject matter relates, in general, to thermoelectric power generation systems, and in particular, to thermoelectric power generation systems for wearable devices.

### BACKGROUND

Thermoelectric effect relates to conversion of temperature gradient to electric voltage. An example of thermoelectric effect is Seebeck effect, according to which a temperature difference between two dissimilar electrical conductors or semiconductors may give rise to a voltage difference between the two conductors or semiconductors. Electrical current generated due to voltage difference may be used for powering various devices working on electricity.

Examples of the devices that may be operated with electric voltage difference obtainable from thermoelectric effect may include wearable devices, such as smart watch and wearable bands. These devices may be powered by thermoelectric effect-based power generators utilising human body heat for generating electricity.

### BRIEF DESCRIPTION OF THE DRAWINGS

The detailed description is described with reference to the accompanying figures. In the figures, the left-most digit(s) of a reference number identifies the figure in which the reference number first appears. The same numbers are used throughout the figures to reference like features and components. Some embodiments of the system(s) in accordance with the present subject matter are described, by way of examples, and with reference to the accompanying figures, in which:

FIG. 1 illustrates a block diagram representation of a power generation system, according to an example implementation of the present subject matter;

FIG. 2 illustrates a block diagram representation of a power generation system, according to an example implementation of the present subject matter;

FIG. 3 illustrates a schematic representation of a power generation system, according to an example implementation of the present subject matter;

FIG. 4 illustrates a block diagram of a power generation system for powering one or more wearable devices, according to an example implementation of the present subject matter;

FIG. 5 illustrates a block diagram of a power generation system for powering one or more wearable devices, according to another example implementation of the present subject matter;

FIG. 6 illustrates a block diagram of a power generation system for powering one or more wearable devices, according to yet another example implementation of the present subject matter;

FIG. 7 illustrates a block diagram of a wearable device, according to an example implementation of the present subject matter;

FIG. 8 illustrates a block diagram of another wearable device, according to an example implementation of the present subject matter;

FIG. 9 illustrates a block diagram representation of another wearable device, according to an example implementation of the present subject matter; and

FIG. 10 illustrates a flowchart of a method of powering a wearable device by a power generation system, according to an example implementation of the present subject matter.

### DETAILED DESCRIPTION

Wearable devices, such as smart watches and wearable bands are becoming increasingly popular. These devices are generally powered by batteries. However, the batteries may not be very suitable for use with the wearable devices as batteries may add significant weight to the wearable devices, thereby making the wearable devices bulky. Further, the batteries may be required to be changed or charged frequently, which makes the overall experience of using the wearable device inconvenient.

Alternatively, the wearable devices may be powered by thermoelectric units based on thermoelectric effect. The wearable devices may be powered by thermoelectric units that may use human body's heat for generating electricity. However, due to low temperature difference between the human body and the thermoelectric unit, voltage difference generated may not be enough for powering devices like wearable devices.

To this, a thermoelectric power generation system, hereinafter referred to as power generation system, is proposed, which powers different types of devices having different requirements and eliminates any requirement of either replacement or frequent recharging. The power generation system is utilized for generating electrical energy based on thermoelectric effect such that the generated electrical energy is sufficient for powering various devices, such as wearable devices.

In an implementation of the present subject matter, the power generation system power generation system includes a thermoelectric unit couplable to a heat source. In one example, the thermoelectric unit is thermoelectric generator. The thermoelectric unit converts heat energy received from the heat source into an electrical voltage based on thermoelectric effect. The heat source can be a source capable of generating and conducting heat. In one example, the heat source can be a human body. Further, a direct current (DC) booster is connected to the thermoelectric unit. The DC booster is to step up the electrical voltage received from the thermoelectric unit. The DC booster is powered from the thermoelectric unit. The input of the DC booster is the output of the thermoelectric unit. Furthermore, a supercapacitor unit is connected to the DC booster. The supercapacitor unit is to store the stepped up electrical voltage from the DC booster. The supercapacitor unit voltage builds up as the current is accumulated from the DC booster.

The thermoelectric unit may convert heat energy into electrical energy based on thermoelectric effect. The thermoelectric unit may receive heat energy from the heat source. Using the heat received from the heat source, the thermoelectric unit may generate electric voltage in the range of 50 mV to 6.6 V. Depending on the temperature difference of human body and the ambient weather conditions the voltage generated varies. For example, in cold weather the thermoelectric unit experiences great temperature difference and generates more voltage and the voltage range indicated here is with the DC booster in place.

In another implementation of the present subject matter, the power generation system includes a step-down DC converter connected between the DC booster and the supercapacitor unit. The step-down DC converter is to step-down the electrical voltage generated by the DC booster. In one example, the output of DC booster is either directed to electronics device like a GPS or GSM unit directly or via the DC step-down DC converter coupled with the supercapacitor unit.

power generation system The DC booster that may step up the voltage as received from the thermoelectric unit. The DC booster may also regulate the voltage output from the thermoelectric unit to provide a steady voltage output. Further, the power generation system includes a supercapacitor unit that may store electrical energy generated by the thermoelectric unit. The supercapacitor may store electric charge until a threshold value, after which the supercapacitor may start discharging the stored electric charge in form of electrical current. The resultant electric voltage from the supercharger powers various devices, such as wearable devices.

The power generation system as described by the present subject matter provides for an alternative power source for powering various devices, such as wearable devices like smart watches and health bands. The power generation system does away with the need of bulky batteries, thereby making the devices compact and lighter in weight. Further, the power generation system eliminates any requirement of either replacement or frequent recharging of the batteries, as the power is generated through the available heat difference. Furthermore, the power generation system employs flexible components, which allows the device employing the power generation system to conform to various shapes thereby adding to the versatility of the device. The power generation system provides for a simple construction which is easy to manufacture. Yet further, the power generation system is capable of providing varying electrical energy depending upon the requirement, thereby enabling the power generation system to power different types of devices having different requirements.

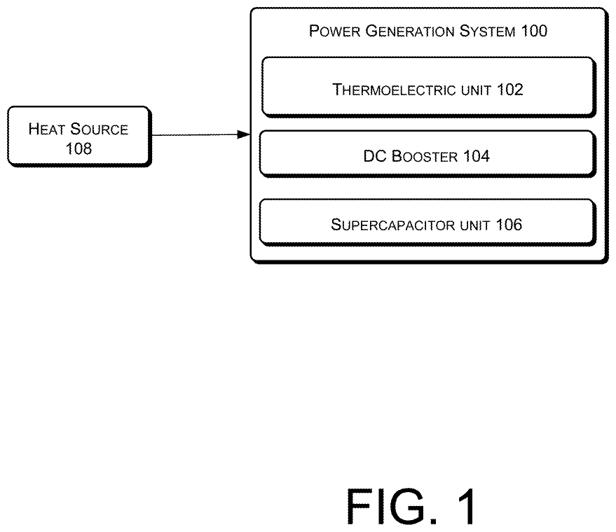

These and other advantages of the present subject matter would be described in a greater detail in conjunction with the FIGS. 1-10 in the following description. The manner in which the power generation system is implemented and operated shall be explained in detail with respect to the FIGS. 1-10.

It should be noted that the description merely illustrates the principles of the present subject matter. It will thus be appreciated that those skilled in the art will be able to devise various arrangements that, although not explicitly described herein, embody the principles of the present subject matter and are included within its scope. Furthermore, all examples recited herein are intended only to aid the reader in understanding the principles of the present subject matter. Moreover, all statements herein reciting principles, aspects and embodiments of the present subject matter, as well as specific examples thereof, are intended to encompass equivalents thereof.

FIG. 1 illustrates a block diagram of a power generation system 100, hereinafter referred to as power generation system 100, for generating electricity from heat energy, as per an implementation of the present subject matter. The power generation system 100 may be implemented as a standalone device, or may have capabilities to communicate with other remote devices, or configurations which allow it to be coupled with other devices, such as a computing device like a phone, a tablet, and a desktop. In other examples, the power generation system 100 may be integrated with other systems.

As shown in FIG. 1, the power generation system 100 includes, among other things, a thermoelectric unit 102, a direct current (DC) booster 104 and a supercapacitor unit 106. In an example, the thermoelectric unit 102 is a thermoelectric electricity generator, such as an electricity generator based on Seebeck effect. The thermoelectric unit 102 generates power based on the Seebeck effect by converting heat into electricity. In an example, the heat energy required for generating electricity may be obtained from a heat source 108. In one example, the heat source 108 can be a human body. The thermoelectric unit 102 may be able to generate voltage in the range of 50 mV to 6.6 V.

The DC booster 104 may step up the voltage as received from the thermoelectric unit 102. Further, the DC booster 104 may regulate the voltage output from the thermoelectric unit 102 to make the voltage output steady. For example, the DC booster 104 may step up voltage and regulate the voltage output from the thermoelectric unit 102 in the range of 50 mV to 6.6 V to a steady voltage supply of 3.4 V. The DC booster 104 may include a DC booster IC to provide a regulated output. The steady voltage supply is in a pulse form due to the design of using the supercapacitor unit 106 with the DC booster 104.

The supercapacitor unit 106 may include one or more supercapacitors (not shown) which may store electrical energy generated by the thermoelectric unit 102. Each supercapacitor of the supercapacitor unit 106 may continue storing electrical energy until reaching a threshold value of 5 Volts. Once the threshold value has been reached, the supercapacitor may then start discharging the stored electrical energy in form of electrical current. The discharging energy may be used to power various devices. The supercapacitors can be made of, but is not limited to, activated carbon, carbon fire cloth, graphene, carbon aerogel, and carbon nanotubes, carbon aerogel.

The power generation system 100 may receive heat supply from the heat source 108 for generating electric power. In an example, the power generation system 100 may be implemented as a wearable device to be worn on the human body.

In operation, a temperature gradient exists between the power generation system 100, in particular the thermoelectric unit 102, and the heat source 108, such that the heat source 108 is at higher temperature than the thermoelectric unit 102. Accordingly, heat may flow from the heat source 108 and the heat supply may be received by the thermoelectric unit 102.

The thermoelectric unit 102 upon receiving the heat supply from the heat source 108 may start generating an electric voltage using the heat supply. As mentioned earlier, the temperature difference between heat source 108 and the thermoelectric unit 102 may be low and, as such, the electric voltage generated by the thermoelectric unit 102 may be low.

The electric voltage generated by the thermoelectric unit 102 is then stepped up by the DC booster 104. For example, the DC booster 104 may convert electric voltage as low as 50 mV generated by the thermoelectric unit 102 to electric voltage as high as 6.6 V.

The power generation system 100 further employs a supercapacitor unit 106. The supercapacitor unit 106 provides for high drive current supply. For example, supercapacitor unit 106 may provide current supply of 2A (Amperes). In an example, the supercapacitor unit 106 includes a charge pump mechanism to provide a pulsed output of 2 A current at voltage of 4V. The supercapacitor unit 106 may further include combination of various circuit elements for achieving the conversion. In one implementation, the supercapacitor unit 106 may be used power various high-power devices, such as a flash of a camera or a flash of camera of a handheld mobile device, such as a smartphone.

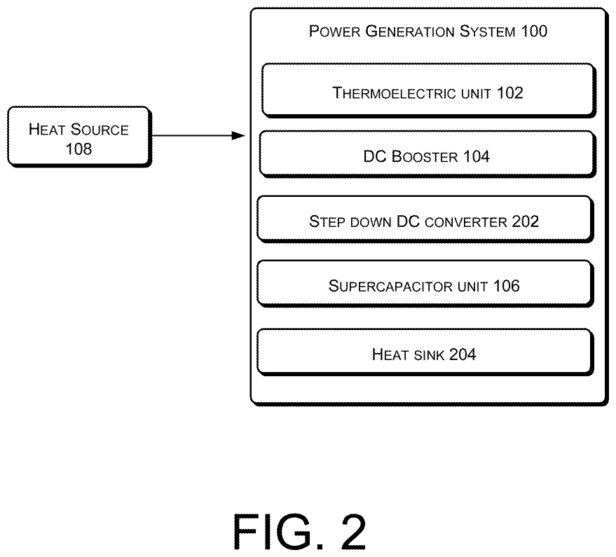

FIG. 2 illustrates block diagram the power generation system 100 for converting heat energy into electric voltage. The power generation system 100 may include the thermoelectric unit 102, the DC booster, a supercapacitor unit 106, and a step-down DC converter 202 connected between the DC booster 104 and the supercapacitor unit 106. Further, the power generation system 100 may receive heat supply from a heat source 108. Furthermore, the power generation system 100 includes a heat sink 204 for dispensing heat.

The thermoelectric unit 102 may be a thermoelectric electricity generator generating electric power by converting heat into electric voltage based on Seebeck effect. Further, the thermoelectric unit 102 may be able to generate voltage in the range of 50 mV to 6.6 V. The DC booster 104 may step up the voltage as received from the thermoelectric unit 102, and may regulate the voltage output from the thermoelectric unit 102 to make the voltage output steady.

The step-down DC converter 202 may be a transformer based step-down DC converter and may be used to bring down the voltage generated by the DC booster.

The conventional systems may employ a voltage regulator to cut off the voltage generated by the thermoelectric unit when the generated voltage rises above a threshold limit. However, using the voltage regulator may not be efficient as the voltage generator may result in loss of usable energy as thermal dissipation of the regulator.

The power generation system 100 of the present subject matter includes the transformer based step-down DC converter which efficiently cuts the high voltage generated by the electricity generator and without letting the energy dissipate as heat. For example, the step-down DC converter 202 may bring the voltage in range of 1.8 V. The resultant voltage may be utilised for powering various devices, such as a GPS unit. In another example, the step-down DC converter may bring the voltage in range of 4V which may be utilised for powering a Global System for Mobile communication (GSM) or a General Packet Radio Service (GPRS) modem. The function of the step-down DC converter 202 is to step the voltage to a desired voltage level by adjusting the onboard potentiometer or configuring resistors. Further, a GSM unit may consume 2 A to 3.4 A to transmit the heart rate and location information for over 2 seconds. The DC booster 104 may allow for converting voltage as low as 50 mV to 6.6V to a steady 3.4V, which may be then used to charge the supercapacitor 106 and is discharged to send the burst of transmitting data packets.

The electrical output from the step-down DC converter may be used for powering various devices. In an example, the device using the electrical output from the step-down DC converter of the power generation system 100 may be implemented as a wearable device for measuring heart rate of the wearer. The wearable device may measure the heart rate by measuring the pulse rate of the wearer. Further, the wearable device may employ a high-power LED based monitor for measuring the pulse rate. The step-down DC converter may provide the required voltage for powering the high-power LED for obtaining the high level of brightness and measuring the pulse rate.

The phone modem needs a peak voltage of not more than 4.4V and is recommended to work at 4V. The step-down DC converter may bring the high voltage generated by the DC booster. The conventional regulators for cutting off voltage to low voltage, such as 5V, are inefficient as lot of usable energy will be lost as thermal dissipation of the regulator. But the transformer-based step-down DC converter stores electrical energy efficiently and converts the same into usable voltage range of 1.8 Volts required for GPS unit and 4V needed for the GSM/GPRS modem.

The supercapacitor unit 106 may store electrical energy generated by the thermoelectric unit 102. In an example, the supercapacitor unit 106 may be employed along with the DC booster and the step-down DC converter to store the electrical energy. The supercapacitor 106 may continue storing electrical energy until reaching a threshold value, following which the supercapacitor 106 may then start discharging the store electrical for powering various devices.

In an example, the supercapacitor unit 106 may employ one or more supercapacitors. Further, the supercapacitor may be a thin sheet-like supercapacitor. In an example, the thickness of the supercapacitor may be equivalent to the thickness of paper in the range of 0.02-0.05 mm. the power generation system 100 may be capable of delivering a pulsed mode current up to 2 A. Further, the supercapacitors of the supercapacitor unit 106 may be flexible so as to allow the power generation system 100 to conform to the different shapes.

Generally, super capacitors may not be able to provide high-drive current of 2 A. The power generation system 100 employs a charge pump to give pulsed output of 2 A current and 4V voltage. Various combinations of circuit elements may be used for this. One application of super capacitors may be for running a camera flash in a camera or a cell phone. The power generation system 100 may convert the low current generated by the electrify generator 102 to a pulsed high-power device. Further, brightness of the LED generated directly from electricity generator may not be sufficient to run a heart rate monitor of a wearable device, such as a fitness tracker. However, the power generation system is capable of measuring heart rate. Further, the power generation system 100 may work in pulsed mode delivering up to 2 A of current with a drop of charging voltage because of the use of a voltage charge pump. The charge pump may be combined with the low-power GSM unit to power a low-power 2G cell-phone at 250 mA. The power generation system may also work with high-power as well as low power GSM Mobile units.

The power generation system 100 includes a heat sink 204 to maximize temperature difference between the heat source and the thermoelectric unit 102. In an example, thermoelectric unit 102 is implemented as a graphite heat sink. Further, the graphite heat sink may be flexible. The heat sink 204 may include flexible pipes with water/cooler liquid in the heat sink 204. In one example, flexible aluminium layers may be used as heat sink 204. The graphite sheets may be used to transfer heat energy from the heat source to heat sink if the heat sink cannot be accommodated at a particular place due to form factor limitations. The graphite heat sink is capable of quickly absorbing heat of and cooling the thermoelectric unit 102, thereby increasing the temperature difference of between the thermoelectric unit 102 and the heat source 108, such as human body.

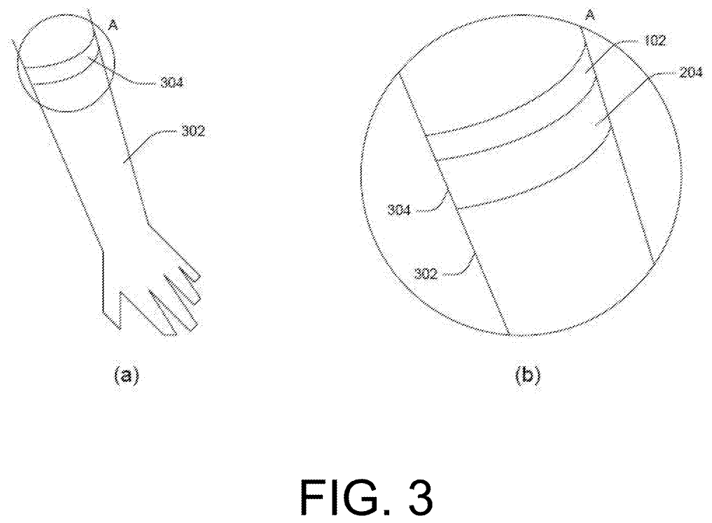

FIG. 3 illustrates system diagram representation of another example power generation system 100 implemented in a wearable device 304. As shown in FIG. 3a, the wearable device 304 may be adapted for wearing on a user's body part, such as wrist and upper arm 302 (near the shoulder). Owing to the flexible construction of power generation system 100, wearable device may easily conform to the shape different body parts of the user. Further, as shown in FIG. 3b, the wearable device 304 includes a power generator 102. Further, the wearable device 304 includes a heat sink 204. In an example, the heat-sink 204 may be made of graphite.

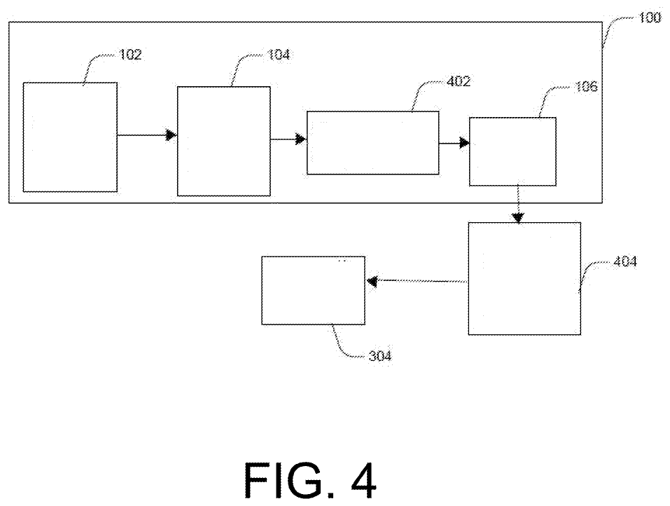

FIG. 4-6 illustrate block diagram representations of example power generation systems 100 implemented to power various wearable devices.

FIG. 4 illustrates a block diagram of the power generation system 100 for powering one or more wearable devices, according to an example implementation of the present subject matter. In FIG. 4, the power generation system 100 includes the thermoelectric unit 102, the DC booster 104, a supercapacitor charging unit 402 and a supercapacitor unit 106. The power generator 100 may be connected to the wearable device 304, such as a geo-cardio data logger via a discharging voltage regulating circuit 404. The wearable device 304 may be a type of wearable device adapted to be worn on the body of the user. The thermoelectric unit 102 may be a Seebeck/Peltier Generator.

The wearable device 304 may comprise a pulse rate sensor, a GPS node and an ultralow power micro-controller/microprocessor. Further, the microcontroller/microprocessor communicates with the GPS module over serial port Tx and Rx pins. It may also read data coming from the pulse rate sensor. The pulse rate sensor may comprise a low power high brightness LED which gets powered by the from the thermoelectric unit 102.

The wearable device 304 may be useful in defence sector where soldiers need to monitor their body stats and location information and send it to rescue authorities or medical teams. This can also be used in athletes or people while doing physical exercise to monitor their body stats and analyse their daily body workouts. This will enable them to manage their diet plans and exercise schedules. Further, the ultralow power microcontroller may run for 6 months to a year on a single coin cell miniature battery.

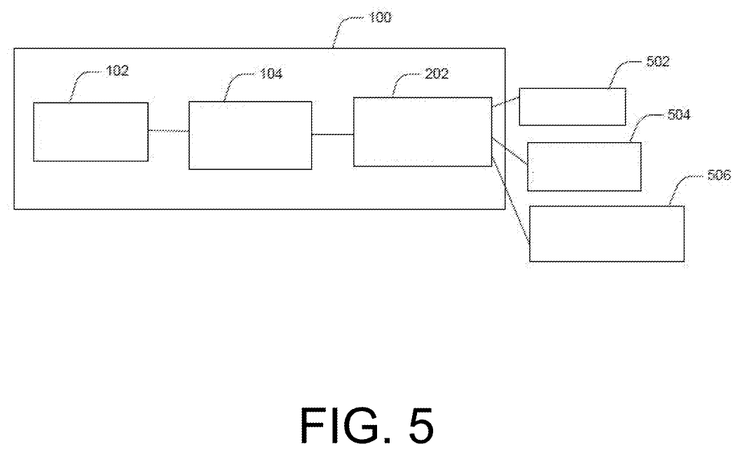

FIG. 5 illustrates a block diagram of the power generation system 100 for powering one or more wearable devices, according to another example implementation of the present subject matter. The power generation system 100 includes the thermoelectric unit 102, the DC booster 104, and the step-down DC converter 202. The step-down DC converter 202 may be a transformer based step-down DC converter. The step-down DC converter 202 may be directly connected to a 1.8V GPS unit 502, 4V GSM (Global System for Mobile communication)/GPRS (General Packet Radio Service) modem 504 and a 1.8V microcontroller unit 506 for powering them.

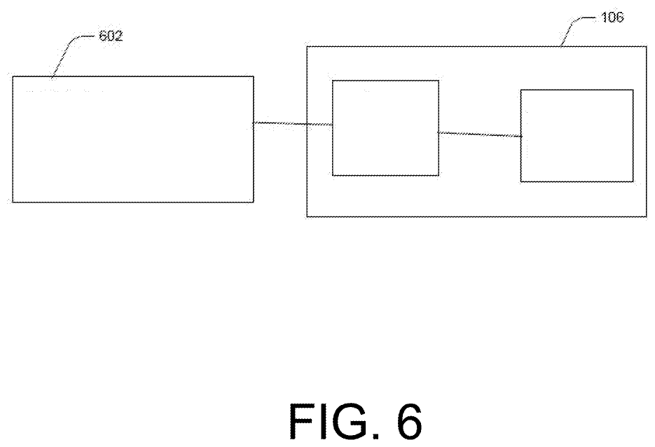

FIG. 6 illustrates a block diagram of the power generation system 100 for powering one or more wearable devices, according to yet another example implementation of the present subject matter. The power generation system 100 includes the supercapacitor unit 106. The power generation system 100 may power a 2 A GSM (Global System for Mobile communication) or a GPRS (General Packet Radio Service) device 602. In an example, the supercapacitor unit 106 may directly supply power to the 2 Ampere GSM or a GPRS device. Further, the supercapacitor unit 106 includes one or more supercapacitors and a charge pump. The charge pump may allow the device to work in pulsed mode delivering up to 2 A of current with a drop of charging voltage. Further, the one or more supercapacitors used in the supercapacitor unit 106 may be a paper-thin supercapacitor which may allow a light and compact construction of the bulky and do not fit in a wrist band which makes it impossible to engineer as a smart band or watch device. The flexible supercapacitors are crucial to the body hugging design to maximize utilization of the heat generated by the human body. In one example, the surface of the hand is curved, flexible Peltier modules and flexible super capacitors and flexible heat sink designs can easily fit onto the surface of the hand and increase the efficiency of the power generation system.

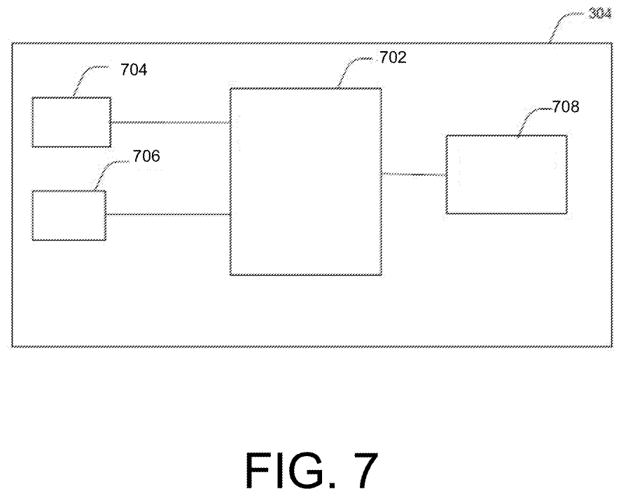

FIG. 7-9 illustrate example wearable devices 304, such as a geo-cardio data logger.

FIG. 7 illustrates a block diagram of the wearable device 304, according to an example implementation of the present subject matter. The wearable device 304 includes an ultra-low power microcontroller 702, a pulse rate sensor 704, a GPS receiver 706, and GSM/GPRS transmitter 708. The ultra-low power microcontroller 702 may have Analog to Digital Converter (ADC) capabilities and a Universal Asynchronous Receiver-Transmitter (UART). In an example, the wearable device 304 may be powered by the power generation system 100 (not shown). The wearable device 304 may be worn on the foot or the chest to optimize its power efficiency. There may also be a provision to read body temperature using the wearable device 304. Further, the wearable device 304 may collect vital statistics of the body of the user and GPS location information. The wearable device 304 may obtain information in pulses (not in a continuous mode) which makes it possible to include a burst mode GSM/GPRS transmitter.

Further, the power generation system 100 may be used for powering wireless communication devices of the wearable device 304. Further, the wireless communication devices may employ any of the conventionally known techniques, such as Bluetooth and Bluetooth-based I-beacon.

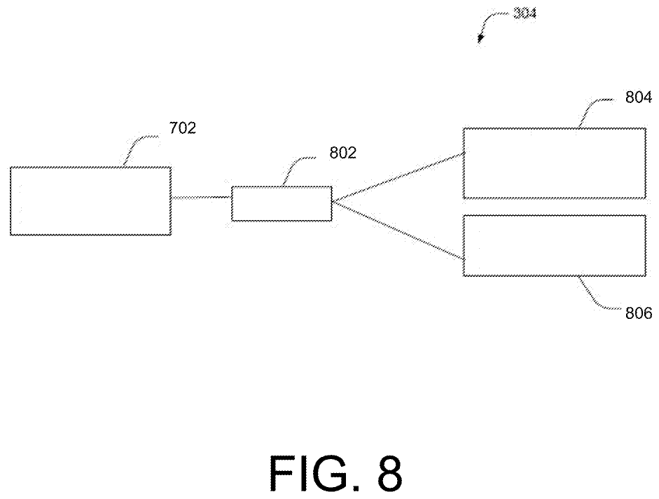

FIG. 8 illustrates a block diagram of another wearable device 304, according to an example implementation of the present subject matter. In one implementation, the wearable device 304 is implemented for performing communication using the I-Beacon technique 802. The wearable device 304 may be able to get location sensitive information, and provide location sensitive tags. Further, the power generation system 100 may also power a Global Positioning System (GPS) unit 804 and a Near-Field Communication (NFC) unit 806. The GPS unit 804 and NFC unit 806 based signal strength monitoring apparatus may be used for giving location sensitive information to the user. Further, the wearable device enabled by the power generation system 100 may provide for limitless geo-tagging all around the world without a physical transmitter. Also, dead-reckoning from an IMU onboard may be used to generate I-beacons indoor.

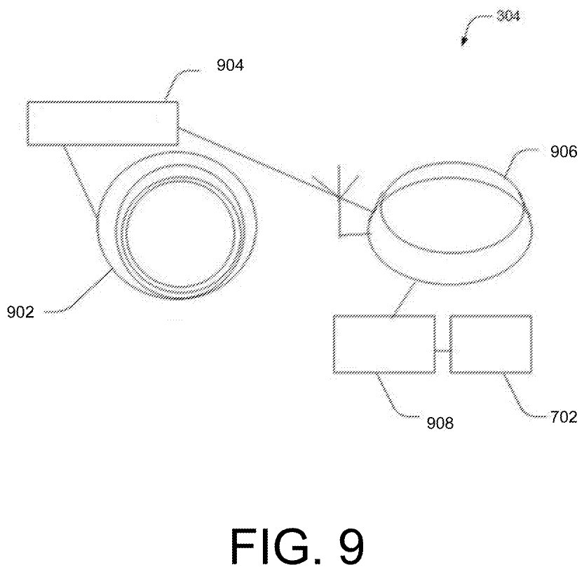

FIG. 9 illustrates a block diagram representation of another wearable device, according to an example implementation of the present subject matter. The wearable device 304 may be implemented for harvesting electrical power through radio signals. The electrical power generated by power generation system 100 may be supplemented by energy harvested through radio signals. The wearable device 304 may include a reception coil 902 having a ferrite core about 1 mm length and diameter of a about two centime meters and a copper coil 906. The reception coil 902 and the copper coil 906 may receive radio signals from local radio or cell phone towers 904 and convert the radio signals into electrical current thereby adding to the electrical output. The copper coil 906 may be connected to a geo cardio power sensor 908. In one example, the geo cardio power sensor 908 may be connected to an ultra-low power microcontroller 702.

In one example, the wearable device 304 may be implemented to identify location and associated services or info tags located at specific locations using machine learning. In another example, the wearable device 304 implemented for use in a hospital setup. The wearable device 304 may include a sensor suited to measure the vital stats of a person's body, which makes it suitable for use in a hospital setup. For example, wearable device 304 may collect his vital stats of a patient wearing the wearable device 304 and send to a central hospital server which again connects to a doctors or nurses tablet computer where they can track the patient's health live. If there are deviations of the vital stats from normal range then alerts can be sent to the doctor's tablet computer. The hospital setup may have multiple number of wearable devices 304 attached to all the patients in the hospital setup. The various wearable devices 304 may connects to the hospitals wi-fi or Bluetooth infrastructure and updates all the data to a central server so that they can be monitored remotely. In yet another example, the wearable device 304 may be implemented in a system for safety of children. The wearable device 304 may be used for tracking children so as to avoid kidnapping of children. The wearable device 304 sends vital stats live to a parent's phone or computer or a surveillance network. When the band is removed the vital stats go offline and this can be used to detect that the child is in trouble and this can be used to alert the security officials. The geo cardio band also sends an alert with the last know location of the patient/child.

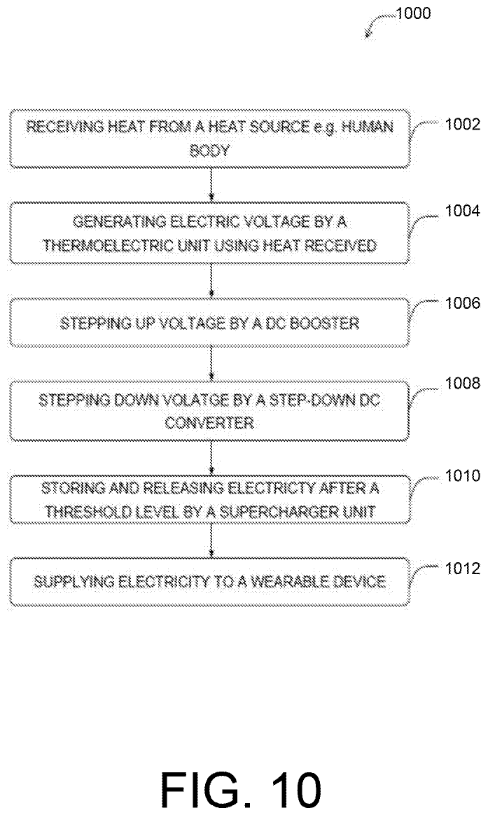

FIG. 10 illustrates a flowchart of a method of powering a wearable device by a power generation system, according to an example implementation of the present subject matter. The order in which the method is described is not intended to be construed as a limitation, and any number of the described method blocks may be combined in any order to implement the aforementioned methods, or an alternative method. Furthermore, the methods 1000 may be implemented by processing resource or computing device(s) through any suitable hardware, non-transitory machine-readable instructions, or combination thereof. The method 1000 is described below with reference to the power generation system 100 as described above; other suitable systems for the execution of these methods may also be utilized. Additionally, implementation of these methods is not limited to such examples.

Returning to FIG. 1000, at block 1002, heat energy may be received from the heat source 108 by the power generation system 100. In an example, the heat source 108 may be a human body, and the power generation system 100 may be implemented in a wearable device worn on a part of the human body. Further, the power generation system 100 may include the thermoelectric unit 102, the DC booster, the step-down DC converter 202, the supercapacitor unit 106, and the heat sink 204.

At block 1004, the heat energy received may be used by the thermoelectric unit 102 for generating electric voltage. The voltage generated by the thermoelectric unit 102 may be in the range of 50 mV to 6.6 V. At step 1006, the electric voltage generated by the thermoelectric unit 102 may be stepped by the DC booster 104. Further, the voltage may be regulated by the DC booster 104 for making the voltage output steady.

At step 1008, the voltage may be brought down by the step-down DC converter 202. The step-down DC converter 202 may be a transformer based step-down DC converter. The voltage generated may be brought down by the step-down DC converter 202 in the range of 1.8 V.

At step 1010, the electrical energy generated may be stored by a supercapacitor unit 106. The electric energy may be stored by the supercapacitor unit 106 until reaching a threshold value, following which the electricity starts discharging. The discharging electricity, at step 1012, is then used to power various electricity-run devices. The electricity-run devices may include wearable devices, such as fitness bands and smartwatches.

Although aspects and features of the present subject matter have been described in the language specific to structural features, it is to be understood that the present subject matter is not necessarily limited to the specific features described. Rather, the specific features are disclosed and explained in the context of a few aspects of the present subject matter.

1. A power generation system (100) comprising:
a thermoelectric unit (102) couplable to a heat source, wherein the thermoelectric unit (102) converts heat energy received from the heat source into an electrical voltage based on thermoelectric effect;
a direct current (DC) booster (104) connected to the thermoelectric unit (102), wherein the DC booster (104) is operative to step up the electrical voltage received from the thermoelectric unit (102);
a supercapacitor unit (106) connected to the DC booster (104), wherein the supercapacitor unit (106) is operative to store the stepped up electrical voltage from the DC booster (104); and
a step-down DC converter (202) connected between the DC booster (104) and the supercapacitor unit (106), wherein the step-down DC converter (202) is operative to step-down the electrical voltage generated by the DC booster (104).

2. The power generation system (100) as claimed in claim 1, wherein the thermoelectric unit (102) is operative to generate the electric voltage in a range of 50 mV to 6.6 V.

3. The power generation system (100) as claimed in claim 1, wherein the DC booster (104) is operative to regulate an output of the electrical voltage from the thermoelectric unit (102).

4. The power generation system (100) as claimed in claim 3, wherein the DC booster (104) is operative to step up the received electrical voltage in a range of 50 mV to 6.6 V and to regulate the output of the received electrical voltage from the thermoelectric unit (102) to a steady voltage supply of 3.4 V.

5. The power generation system (100) as claimed in claim 1, wherein the supercapacitor unit (106) stores the stepped up electrical voltage from the DC booster (104) until the stepped up electrical voltage reaches a threshold value, and wherein upon reaching the threshold value, the supercapacitor unit (106) starts discharging the stored electric voltage in form of an electrical current.

6. The power generation system (100) as claimed in claim 5, wherein the supercapacitor unit (106) comprises one or more supercapacitors.

7. The power generation system (100) as claimed in claim 6, wherein the supercapacitor unit (106) is operative storing the electrical voltage until reaching the threshold value of 5V.

8. The power generation system (100) as claimed in claim 5, wherein the supercapacitor unit (106) is operative to provide the electrical current of 2 Amperes.

9. The power generation system (100) as claimed in claim 8, wherein the supercapacitor unit (106) comprises a charge pump mechanism operative to provide a pulsed output the electrical current of 2 Amperes at the electrical voltage of 4V.

10. The power generation system (100) as claimed in claim 1, wherein the power generation system (100) comprises a heat sink (204) for maximizing a temperature difference between the heat source (108) and the thermoelectric unit (102).

11. The power generation system (100) as claimed in claim 1, wherein the step-down DC converter (202) is a transformer based step-down DC converter.

12. The power generation system (100) as claimed in claim 6, wherein each supercapacitor of the one or more supercapacitors is a thin sheet-like supercapacitor.

13. The power generation system (100) as claimed in claim 12, wherein each supercapacitor has a thickness in a range of 0.02-0.05 mm.

14. The power generation system (100) as claimed in claim 12, wherein each supercapacitor is flexible to conform to different shapes.

15. The power generation system (100) as claimed in claim 10, wherein the heat sink (204) is a graphite heat sink.

16. The power generation system (100) as claimed in claim 15, wherein the graphite heat sink is flexible.

17. The power generation system (100) as claimed in claim 1, wherein the power generation system (100) is flexible.

18. A wearable device powered by a power generation system (100) as claimed in claim 1.
